(19) United States
(12) Patent Application Publication
(10) Pub. No.: US 2025/0013142 A1
(43) Pub. Date: Jan. 9, 2025

(54) PELLICLES AND MEMBRANES FOR USE IN A LITHOGRAPHIC APPARATUS

(71) Applicant: ASML NETHERLANDS B.V., Veldhoven (NL)

(72) Inventors: Zomer Silvester HOUWELING, Utrecht (NL); Paul Alexander VERMEULEN, Best (NL); Alexander Ludwig KLEIN, Eindhoven (NL)

(73) Assignee: ASML NETHERLANDS B.V., Veldhoven (NL)

(21) Appl. No.: 18/708,573

(22) PCT Filed: Nov. 11, 2022
(86) PCT No.: PCT/EP2022/081574

§ 371 Date: May 8, 2024

(30) Foreign Application Priority Data
Nov. 25, 2021 (EP) 21210424.4

(51) Int. Cl. G03F 1/62; G03F 7/00

(52) U.S. Cl. CPC G03F 1/62; G03F 7/70983

(57) ABSTRACT

A method for forming a pellicle for use in a lithographic apparatus is disclosed. The method includes: providing a porous membrane formed from a first material; applying at least one layer of two-dimensional material to at least one side of the porous membrane; and applying a capping layer to the at least one layer of two-dimensional material on at least one side of the porous membrane such that the at least one layer of two-dimensional material is disposed between the or each capping layer and the porous membrane. The at least one layer of two-dimensional material may act to close the adjacent side of the porous membrane and to form a smoother and flatter exterior surface of the pellicle. Advantageously, this may allow the porous membrane to be protected from etching while reducing EUV flare, regardless of the material used for the capping layer.

### CROSS-REFERENCE TO RELATED APPLICATIONS

This application claims priority of EP application 21210424.4 which was filed on Nov. 25, 2021 and which is incorporated herein in its entirety by reference.

### FIELD

The present invention relates to pellicles for use in a lithographic apparatus and associated methods for forming such pellicles. The present invention also relates to a lithographic apparatus comprising a membrane disposed in a path of a radiation beam of the lithographic apparatus (used for forming an image on a substrate).

### BACKGROUND

A lithographic apparatus is a machine constructed to apply a desired pattern onto a substrate. A lithographic apparatus can be used, for example, in the manufacture of integrated circuits (ICs). A lithographic apparatus may for example project a pattern from a patterning device (e.g., a mask) onto a layer of radiation-sensitive material (resist) provided on a substrate.

The wavelength of radiation used by a lithographic apparatus to project a pattern onto a substrate determines the minimum size of features that can be formed on that substrate. A lithographic apparatus that uses EUV radiation, being electromagnetic radiation having a wavelength within the range 4-20 nm, may be used to form smaller features on a substrate than a conventional lithographic apparatus (which may for example use electromagnetic radiation with a wavelength of 193 nm).

A patterning device (e.g., a mask) that is used to impart a pattern to a radiation beam in a lithographic apparatus may form part of a mask assembly. A mask assembly may include a pellicle that protects the patterning device from particle contamination. The pellicle may be supported by a pellicle frame.

It may be desirable to provide an apparatus and/or method that obviates or mitigates one or more problems associated with the prior art.

### SUMMARY

According to a first aspect of the present disclosure there is provided a method for forming a pellicle for use in a lithographic apparatus, the method comprising: providing a porous membrane formed from a first material; applying at least one layer of two-dimensional material to at least one side of the porous membrane; and applying a capping layer to the at least one layer of two-dimensional material on at least one side of the porous membrane such that the at least one layer of two-dimensional material is disposed between the or each capping layer and the porous membrane.

The pellicle may be suitable for use adjacent to a reticle within an EUV lithographic apparatus. In use, such a (reflective) reticle is illuminated with EUV radiation, for example from an illumination system. It will be appreciated that the reticle is configured to impart the radiation beam received from the illumination system with a pattern in its cross-section to form a patterned radiation beam. A projection system collects the (reflected) patterned radiation beam and forms a (diffraction-limited) image of the reticle on a substrate (for example a resist coated silicon wafer). Any contamination on the reticle will, in general, alter the image formed on the substrate, leading to printing errors.

To avoid particle contamination of the reticles, it is known to use a thin membrane, known as a pellicle, to protect the reticle. The pellicle is disposed in front of the reticle and prevents particles from the landing on the reticle. The pellicle is disposed such that it is not sharply imaged by the projection system and therefore particles on the pellicle do not interfere with the imaging process. It is desirable for the pellicle to be sufficiently thick that it stops particles from impinging on the reticle that would cause unacceptable printing errors but as thin as possible to reduce the absorption of EUV radiation by the pellicle.

The method of forming a pellicle according to the first aspect is particularly advantageous, as now discussed.

It will be appreciated that as used here a porous membrane is intended to mean a material with an open structure such as, for example, a nanotube membrane. It will be appreciated that as used here a two-dimensional material is intended to mean a material formed from one or more single atom layers such as, for example, graphene. The at least one layer of two-dimensional material acts to close the adjacent side of the porous membrane.

It will be appreciated that a non-porous membrane may have two generally parallel surfaces that define two opposed sides of the membrane. A volume bounded by the two generally parallel surfaces is substantially occupied by the material from which the non-porous membrane is formed. It will be further appreciated that, in contrast, a porous membrane comprises regions which are occupied by a material from which the porous membrane is formed interspersed with voids which have no material. For such a porous membrane two generally parallel imaginary or non-physical surfaces may define the boundaries or sides of the membrane. The volume bounded by the two generally parallel imaginary surfaces is only partially occupied by the material from which the porous membrane is formed. Applying at least one layer of two-dimensional material to at least one side of the porous membrane is intended to include applying the at least one layer of two-dimensional material to at least one imaginary or non-physical surface that defines a boundary or side of the porous membrane.

The method according to the first aspect results in a pellicle wherein a bulk of the pellicle is formed from a porous material. Advantageously, this can result in a pellicle with a reduced density and, therefore, an increased transmissivity for extreme ultraviolet (EUV) radiation. This is particularly important for EUV lithography systems and improves throughput of the system.

One particularly promising material for use as a pellicle membrane in an EUV lithographic apparatus is a fabric or membrane formed from carbon nanotubes (CNTs). Such a CNT pellicle is a porous material and, therefore, can provide very high EUV transmission (of >98%). Furthermore, CNT pellicles also provide very good mechanical stability and can therefore be manufactured at small thicknesses, whilst remaining robust against mechanical failure. However, a low pressure hydrogen gas is typically provided within the lithographic apparatus, which forms a hydrogen plasma in the presence of the EUV radiation (during exposure). It has been found that hydrogen ions and hydrogen free radicals from the hydrogen plasma can etch pellicles formed from CNTs, limiting the potential lifetime of the pellicle and blocking commercial implementation of CNT pellicles.

In order to mitigate such etching of CNT pellicles, it has previously been proposed to provide such CNT pellicles with a protective, capping layer. Such a capping layer may be formed from a material which is chemically stable in the environment of the lithographic apparatus and which has a low extinction coefficient for EUV radiation.

However, a difference between the refractive indices of carbon and suitable capping layers is typically larger than a difference between the refractive indices of carbon and the vacuum. Therefore, the inventors have realized that such a capping layer will result in an increase in EUV flare, which is undesirable. Applying at least one layer of two-dimensional material to the porous membrane and then subsequently applying a capping layer to the at least one layer of two-dimensional material (as specified by the method according to the first aspect) is particularly advantageous, as now discussed.

It will be appreciated that a porous material will have a structure and therefore if there is a large contrast between the refractive index of the porous material and the surrounding medium, as radiation (for example EUV radiation) propagates through the pellicle the radiation will be scattered (for example via Mie scattering). This will lead to undesirable diffusion or flare of the radiation, again impacting on the imaging performance of the lithographic apparatus. Since EUV radiation is so strongly absorbed by most materials, EUV lithographic systems are typically operated at high vacuum. Therefore, it may be particularly desirable for the porous material to be formed from material having a refractive index close to 1. It may also be desirable for the porous material to be formed from a material having an extinction coefficient for EUV radiation which is as low as possible.

The at least one layer of two-dimensional material of the method according to the first aspect acts to close the adjacent side of the porous membrane and to form a smoother and flatter exterior surface of the pellicle. This allows for the capping layer to be provided over said smoother and flatter exterior surface. Advantageously, this allows the porous membrane to be protected from etching whilst reducing EUV flare, regardless of the material used for the capping layer. Furthermore, in addition to being significantly smoother and flatter than a surface of the porous material, the surface of the two dimensional material will have a smaller surface area. As a result, when a (relatively thin) capping layer is provided on the two dimensional material rather than directly on the porous material, a volume of the capping layer is reduced. Advantageously, this also results in a higher EUV transmissivity of the pellicle for the same thickness of capping layer.

Within a CNT membrane the carbon nanotubes may be separate or, alternatively, they may clump together in bundles. Furthermore, the size of such bundles may vary. It has been found by the inventors that when a capping layer is applied directly to a CNT membrane, the loss of EUV transmissivity due to a capping layer is strongly dependent on an extent of bundling within the CNT membrane. For example, for a fixed density of CNTs in the membrane, the smaller the number of CNTs per bundle, the larger the loss of EUV transmissivity will be. Advantageously, by using the method according to the first aspect, since the capping layer is applied to the at least one layer of two-dimensional material (rather than the porous membrane) the loss of EUV transmissivity is no longer dependent in the typical size of structures within the porous membrane (for example the amount of bundling in the case of a CNT membrane). In fact, by applying it to the flat layers of two-dimensional, for a given thickness of capping layer the loss of EUV transmissivity is minimized.

Finally, the at least one layer of two-dimensional material of the pellicle formed using the method according to the first aspect closes the structure of the porous layer. Advantageously, this results in a higher particle stopping power than a CNT pellicle without such layers of two-dimensional material.

The application of at least one layer of two-dimensional material to at least one side of the porous membrane may be achieved using a wet transfer process.

Such a wet transfer process is known in the art. Typically, the wet transfer process comprises the growth of a two-dimensional material (for example a graphene film) on a first substrate (for example a copper substrate). Subsequently, an adhesion layer is formed on the other side of the two-dimensional material. The adhesion layer may, for example, comprise a polymer such as, for example, polymethyl methacrylate (PMMA). Subsequently, the first substrate is removed, for example by selective etching. For example, a first substrate comprising copper may be removed using ammonium persulphate. Optionally, the adhesion layer and the two-dimensional material may be rinsed (for example in water). Subsequently, the two-dimensional material is applied to a side of the porous membrane. Finally, the adhesion layer is removed, for example by selective etching.

Applying at least one layer of two-dimensional material to at least one side of the porous membrane may comprise: providing at least one layer of two-dimensional material on a support substrate; pressing the at least one layer of two-dimensional material to a side of the porous membrane; and removing the support substrate.

The support substrate may comprise a sacrificial layer on a surface thereof. The at least one layer of two-dimensional material may be provided on the sacrificial layer. Removing the support substrate may comprise etching the sacrificial layer to remove the support substrate.

The porous membrane may comprise a nanostructure.

The porous membrane may comprise nanotubes.

For example, the porous membrane may be a fabric formed from CNTs. This may be referred to as a carbon nanotube membrane (CNTm).

The porous membrane may be substantially self-supporting.

It will be appreciated that, in use, a pellicle will be supported around its periphery by a pellicle frame, which is mounted to a reticle or mask. As used here, the porous membrane being substantially self-supporting is intended to mean that the porous membrane supports its own weight. That is, there is no additional membrane adjacent the porous membrane providing support for the porous membrane, other than the at least one layer of two-dimensional material and the capping layer.

In some embodiments, the porous membrane may be considered to form a majority of the thickness of the pellicle.

The or each at least one layer of two-dimensional material may be applied as a substantially continuous layer adjacent the at least one side of the porous membrane.

The two-dimensional material may comprise graphene.

In some embodiments 3 layers of graphene may be provided adjacent one or both sides of the porous membrane.

In one embodiment, the porous membrane may be a carbon nanotube membrane and the two-dimensional material comprises graphene. One benefit of using graphene as the two-dimensional material is that pellicles have previously been formed from carbon and the properties of carbon in this environment are known. For example, by using another carbon based material such as graphene large increases in EUV reflection (which may result from other materials) may be avoided. Furthermore, other materials may have an increased susceptibility to the hydrogen etching within the lithographic apparatus.

The two-dimensional material may comprise hexagonal boron nitride (h-BN).

The two-dimensional material may comprise molybdenum disulfide (MoS2).

Advantageously, these materials (h-BN and MoS2) are robust against hydrogen etching and therefore for embodiments wherein the two-dimensional material comprises hexagonal boron nitride (h-BN) and/or molybdenum disulfide (MoS2) a capping layer having a smaller thickness may be applied.

In some embodiments, at least one layer of two-dimensional material may be applied to both sides of the porous membrane and a capping layer may be applied on each side of the pellicle such that the at least one layer of two-dimensional material is disposed between a capping layer and the porous membrane.

It will be appreciated that different types of two-dimensional material may be provided on different sides of the porous membrane.

The or each capping layer may be a three-dimensional material.

Advantageously, three-dimensional materials are significantly easier to manufacture than two-dimensional materials. As discussed above, the two-dimensional material effectively closes the structure of the porous membrane. This allows three-dimensional materials to be used for the capping layer whilst enjoying the benefits of the pellicle according to the second aspect, as discussed above.

A total EUV transmissivity of the or each capping layer may be 96% or more.

It will be appreciated that unless otherwise stated, herein a total EUV transmissivity of the capping layer is intended to mean the percentage of EUV radiation that is transmitted after propagating through the pellicle. For embodiments wherein a capping layer is provided on each side of the pellicle the total EUV transmissivity of the capping layers means the total transmissivity from both sides.

In some embodiments, the total EUV transmissivity of the at least one capping layer may be 96.5% or more. In some embodiments, the total EUV transmissivity of the at least one capping layer may be 97% or more. In some embodiments, the total EUV transmissivity of the at least one capping layer may be 97.5% or more. In some embodiments, the total EUV transmissivity of the at least one capping layer be of the order of 97.8%.

It will be appreciated that the EUV transmissivity of the capping layer is, in general, dependent on (a) the type of material(s) from which the capping layer is formed; and (b) a thickness of the capping layer. It will be appreciated that the EUV transmissivity of the capping layer is, in general, also dependent on a density or porosity of the capping layer. Example materials are discussed below.

The at least one capping layer may be suitable to protect the porous layer and the at least one layer of two-dimensional material from hydrogen etching.

It will be appreciated that in order to be suitable to protect the other two layers from hydrogen etching, the capping layer (a) may be formed from a suitable material that is not strongly etched by hydrogen; and (b) may have a suitable thickness. Example materials are discussed below.

The at least one capping layer may be formed from a material having an extinction coefficient for EUV radiation of less than 0.02 nm⁻¹.

It is desirable to minimize the absorption of EUV radiation by the pellicle. Therefore, it is generally desirable to form the capping layer from a material having the smallest extinction coefficient for EUV radiation possible.

In some embodiments, the capping layer is formed from a material having an extinction coefficient for EUV radiation of less than 0.01 nm⁻¹. In some embodiments, the capping layer is formed from a material having an extinction coefficient for EUV radiation of less than 0.005 nm⁻¹.

The capping layer may have a thickness of the order of 0.3 to 5 nm.

The capping layer may comprise yttrium or yttrium oxide.

Yttrium has an extinction coefficient for EUV radiation of the order of 0.0021 nm⁻¹. Yttrium oxide (Y₂O₃) has an extinction coefficient for EUV radiation of the order of 0.01 nm⁻¹.

The capping layer may comprise any of the following: aluminium oxide (Al₂O₃), hafnium oxide (HfO₂), zirconium oxide (ZrO₂), ruthenium (Ru), platinum (Pt), gold (Au), zirconium nitride (ZrN), aluminium (Al) or zirconium (Zr).

The method may further comprise attaching a pellicle border to a periphery of the porous membrane.

The pellicle border may be attached to the periphery of the porous membrane before the at least one layer of two-dimensional material is applied to at least one side of the porous membrane.

According to a second aspect of the present disclosure there is provided a pellicle for use in a lithographic apparatus, the pellicle comprising: a porous membrane formed from a first material; at least one layer of two-dimensional material adjacent at least one side of the porous membrane; and at least one capping layer adjacent the at least one layer of two-dimensional material such that the at least one layer of two-dimensional material is disposed between the or each capping layer and the porous membrane.

The pellicle according to the second aspect of the present disclosure may be formed using the method according to the first aspect of the present disclosure. The pellicle according to the second aspect of the present disclosure may have any feature that may result from any feature of the method according to the first aspect of the present disclosure.

The pellicle may be suitable for use adjacent to a reticle within an EUV lithographic apparatus. In use, such a (reflective) reticle is illuminated with EUV radiation, for example from an illumination system. It will be appreciated that the reticle is configured to impart the radiation beam received from the illumination system with a pattern in its cross-section to form a patterned radiation beam. A projection system collects the (reflected) patterned radiation beam and forms a (diffraction-limited) image of the reticle on a substrate (for example a resist coated silicon wafer). Any contamination on the reticle will, in general, alter the image formed on the substrate, leading to printing errors.

To avoid particle contamination of the reticles, it is known to use a thin membrane, known as a pellicle, to protect the reticle. The pellicle is disposed in front of the reticle and prevents particles from the landing on the reticle. The pellicle is disposed such that it is not sharply imaged by the projection system and therefore particles on the pellicle do not interfere with the imaging process. It is desirable for the pellicle to be sufficiently thick that it stops particles from impinging on the reticle that would cause unacceptable printing errors but as thin as possible to reduce the absorption of EUV radiation by the pellicle.

The pellicle according to the second aspect is particularly advantageous, as now discussed.

It will be appreciated that as used here a porous membrane is intended to mean a material with an open structure such as, for example, a nanotube membrane. It will be appreciated that as used here a two-dimensional material is intended to mean a material formed from one or more single atom layers such as, for example, graphene. The at least one layer of two-dimensional material acts to close the adjacent side of the porous membrane.

The pellicle according to the second aspect allows for a bulk of the pellicle to be formed from a porous material. Advantageously, this can result in a pellicle with a reduced density and, therefore, an increased transmissivity for extreme ultraviolet (EUV) radiation. This is particularly important for EUV lithography systems and improves throughput of the system.

It will be appreciated that a porous material will have a structure and therefore if there is a large contrast between the refractive index of the porous material and the surrounding medium, as radiation (for example EUV radiation) propagates through the pellicle the radiation will be scattered (for example via Mie scattering). This will lead to undesirable diffusion or flare of the radiation, again impacting on the imaging performance of the lithographic apparatus. Since EUV radiation is so strongly absorbed by most materials, EUV lithographic systems are typically operated at high vacuum. Therefore, it may be particularly desirable for the porous material to be formed from material having a refractive index close to 1. It may also be desirable for the porous material to be formed from a material having an extinction coefficient for EUV radiation which is as low as possible.

One particularly promising material for use as a pellicle membrane in an EUV lithographic apparatus is a fabric or membrane formed from carbon nanotubes (CNTs). Such a CNT pellicle is a porous material and, therefore, can provide very high EUV transmission (of >98%). Furthermore, CNT pellicles also provide very good mechanical stability and can therefore be manufactured at small thicknesses, whilst remaining robust against mechanical failure. However, a low pressure hydrogen gas is typically provided within the lithographic apparatus, which forms a hydrogen plasma in the presence of the EUV radiation (during exposure). It has been found that hydrogen ions and hydrogen free radicals from the hydrogen plasma can etch pellicles formed from CNTs, limiting the potential lifetime of the pellicle and blocking commercial implementation of CNT pellicles.

In order to mitigate such etching of CNT pellicles, it has previously been proposed to provide such CNT pellicles with a protecting, capping layer. However, a difference between the refractive indices of carbon and suitable capping layers is typically larger than a difference between the refractive indices of carbon and the vacuum. Therefore, such a capping layer will result in an increase in EUV flare, which is undesirable. The at least one layer of two-dimensional material of the pellicle according to the second aspect acts to close the adjacent side of the porous membrane and to form a smoother and flatter exterior surface of the pellicle. This allows for a capping layer to be provided over said smoother and flatter exterior surface. Advantageously, this allows the porous membrane to be protected from etching whilst reducing EUV flare, regardless of the material used for the capping layer. Furthermore, in addition to being significantly smoother and flatter than a surface of the porous material, the surface of the two dimensional material will have a smaller surface area. As a result, when a (relatively thin) capping layer is provided on the two dimensional material rather than directly on the porous material, a volume of the capping layer is reduced. Advantageously, this also results in a higher EUV transmissivity of the pellicle for the same thickness of capping layer.

Within a CNT membrane the carbon nanotubes may be separate or, alternatively, they may clump together in bundles. Furthermore, the size of such bundles may vary. It has been found by the inventors that when a capping layer is applied directly to a CNT membrane, the loss of EUV transmissivity due to a capping layer is strongly dependent on an extent of bundling within the CNT membrane. For example, for a fixed density of CNTs in the membrane, the smaller the number of CNTs per bundle, the larger the loss of EUV transmissivity will be. Advantageously, with the pellicle according to the second aspect, since the capping layer is applied to the at least one layer of two-dimensional material (rather than the porous membrane) the loss of EUV transmissivity is no longer dependent in the typical size of structures within the porous membrane (for example the amount of bundling in the case of a CNT membrane). In fact, by applying it to the flat layers of two-dimensional, for a given thickness of capping layer the loss of EUV transmissivity is minimized.

Finally, the at least one layer of two-dimensional material of the pellicle according to the second aspect closes the structure of the porous layer. Advantageously, this results in a higher particle stopping power than a CNT pellicle without such layers of two-dimensional material.

The porous membrane may comprise a nanostructure.

The porous membrane may comprise nanotubes.

For example, the porous membrane may be a fabric formed from CNTs. This may be referred to as a carbon nanotube membrane.

The porous membrane may be substantially self-supporting.

It will be appreciated that, in use, a pellicle will be supported around its periphery by a pellicle frame, which is mounted to a reticle or mask. As used here, the porous membrane being substantially self-supporting is intended to mean that the porous membrane supports its own weight. That is, there is no additional membrane adjacent the porous membrane providing support for the porous membrane, other than the at least one layer of two-dimensional material.

The porous membrane may be considered to form a majority of the thickness of the pellicle.

The or each at least one layer of two-dimensional material may form a substantially continuous layer adjacent the at least one side of the porous membrane.

The two-dimensional material may comprise graphene.

In some embodiments 3 layers of graphene may be provided adjacent one or both sides of the porous membrane.

In one embodiment, the porous membrane may be a carbon nanotube membrane and the two-dimensional material comprises graphene. One benefit of using graphene as the two-dimensional material is that pellicles have previously been formed from carbon and the properties of carbon in this environment are known. For example, by using another carbon based material such as graphene large increases in EUV reflection (which may result from other materials) may be avoided. Furthermore, other materials may have an increased susceptibility to the hydrogen etching within the lithographic apparatus.

The two-dimensional material may comprise hexagonal boron nitride (h-BN).

The two-dimensional material may comprise molybdenum disulfide (MoS2).

Advantageously, these materials (h-BN and MoS2) are robust against hydrogen etching and therefore for embodiments wherein the two-dimensional material comprises hexagonal boron nitride (h-BN) and/or molybdenum disulfide (MoS2) a capping layer having a smaller thickness may be applied.

In some embodiments, at least one layer of two-dimensional material may be provided adjacent to both sides of the porous membrane and a capping layer may be provided on each side of the pellicle such that the at least one layer of two-dimensional material is disposed between a capping layer and the porous membrane.

It will be appreciated that different types of two-dimensional material may be provided on different sides of the porous membrane.

The or each capping layer may be a three-dimensional material.

Advantageously, three-dimensional materials are significantly easier to manufacture than two-dimensional materials. As discussed above, the two-dimensional material effectively closes the structure of the porous membrane. This allows three-dimensional materials to be used for the capping layer whilst enjoying the benefits of the pellicle according to the second aspect, as discussed above.

A total EUV transmissivity of the or each capping layer may be 96% or more.

It will be appreciated that unless otherwise stated, herein a total EUV transmissivity of the capping layer is intended to mean the percentage of EUV radiation that is transmitted after propagating through the pellicle. For embodiments wherein a capping layer is provided on each side of the pellicle the total EUV transmissivity of the capping layers means the total transmissivity from both sides.

In some embodiments, the total EUV transmissivity of the at least one capping layer may be 96.5% or more. In some embodiments, the total EUV transmissivity of the at least one capping layer may be 97% or more. In some embodiments, the total EUV transmissivity of the at least one capping layer may be 97.5% or more. In some embodiments, the total EUV transmissivity of the at least one capping layer be of the order of 97.8%.

It will be appreciated that the EUV transmissivity of the capping layer is, in general, dependent on (a) the type of material(s) from which the capping layer is formed; and (b) a thickness of the capping layer. It will be appreciated that the EUV transmissivity of the capping layer is, in general, also dependent on a density or porosity of the capping layer. Example materials are discussed below.

The at least one capping layer may be suitable to protect the porous layer and the at least one layer of two-dimensional material from hydrogen etching.

It will be appreciated that in order to be suitable to protect the other two layers from hydrogen etching, the capping layer (a) may be formed from a suitable material that is not strongly etched by hydrogen; and (b) may have a suitable thickness. Example materials are discussed below.

The at least one capping layer may be formed from a material having an extinction coefficient for EUV radiation of less than 0.02 nm⁻¹.

It is desirable to minimize the absorption of EUV radiation by the pellicle. Therefore, it is generally desirable to form the capping layer from a material having the smallest extinction coefficient for EUV radiation possible.

In some embodiments, the capping layer is formed from a material having an extinction coefficient for EUV radiation of less than 0.01 nm⁻¹. In some embodiments, the capping layer is formed from a material having an extinction coefficient for EUV radiation of less than 0.005 nm⁻¹.

The capping layer may have a thickness of the order of 0.3 to 5 nm.

The capping layer may comprise yttrium or yttrium oxide.

Yttrium has an extinction coefficient for EUV radiation of the order of 0.0021 nm⁻¹. Yttrium oxide (Y₂O₃) has an extinction coefficient for EUV radiation of the order of 0.01 nm⁻¹.

The capping layer may comprises any of the following: aluminium oxide (Al₂O₃), hafnium oxide (HfO₂), zirconium oxide (ZrO₂), ruthenium (Ru), platinum (Pt), gold (Au), zirconium nitride (ZrN), aluminium (Al) or zirconium (Zr).

The capping layer may comprise a plurality of sublayers formed from different materials.

The pellicle may further comprise a pellicle border at a periphery of the porous membrane.

According to a third aspect of the present disclosure there is provided a lithographic apparatus operable to form an image of a patterning device on a substrate using a radiation beam, the lithographic apparatus comprising a membrane disposed in a path of the radiation beam, the membrane comprising: a porous membrane formed from a first material; at least one layer of two-dimensional material adjacent at least one side of the porous membrane; and at least one capping layer adjacent the at least one layer of two-dimensional material such that the at least one layer of two-dimensional material is disposed between the or each capping layer and the porous membrane.

It will be appreciated that the membrane according to the third aspect is substantially the same as the pellicle according to the second aspect. Furthermore, since the membrane according to the third aspect also forms a transmissive membrane within a lithographic apparatus, it is advantageous for same reasons as the pellicle according to the second aspect, as set out above.

The membrane disposed in a path of the radiation beam in the lithographic apparatus according to the third aspect of the present disclosure may be formed using the method according to the first aspect of the present disclosure. The membrane disposed in a path of the radiation beam in the lithographic apparatus according to the third aspect of the present disclosure may have any feature that may result from any feature of the method according to the first aspect of the present disclosure. Similarly, the membrane disposed in a path of the radiation beam in the lithographic apparatus according to the third aspect of the present disclosure may have any feature of the pellicle according to the second aspect of the present disclosure.

The membrane may form part of a dynamic gas lock.

Such a dynamic gas lock may be formed, for example, proximate to an opening for the radiation beam to pass from a projection system of the lithographic apparatus to a substrate supported on a substrate table.

Alternatively, the membrane may form part of a spectral filter.

Such a spectral filter may be provided in any convenient or suitable position within the lithographic apparatus. The spectral filter may be arranged to avoid, or at least reduce, out of band radiation from being incident on a substrate supported on a substrate table.

The membrane according to the third aspect may have any of the features of the pellicle according to the second aspect as set out above, as now discussed.

The porous membrane may comprise a nanostructure.

The porous membrane may comprise nanotubes.

For example, the porous membrane may be a fabric formed from CNTs. This may be referred to as a carbon nanotube membrane.

The porous membrane may be substantially self-supporting.

It will be appreciated that, in use, the membrane will be supported around its periphery by a support frame. As used here, the porous membrane being substantially self-supporting is intended to mean that the porous membrane supports its own weight. That is, there is no additional membrane adjacent the porous membrane providing support for the porous membrane, other than the at least one layer of two-dimensional material.

The porous membrane may be considered to form a majority of the thickness of the membrane.

The or each at least one layer of two-dimensional material may form a substantially continuous layer adjacent the at least one side of the porous membrane.

The two-dimensional material may comprise graphene.

In some embodiments 3 layers of graphene may be provided adjacent one or both sides of the porous membrane.

In one embodiment, the porous membrane may be a carbon nanotube membrane and the two-dimensional material comprises graphene. One benefit of using graphene as the two-dimensional material is that pellicles have previously been formed from carbon and the properties of carbon in this environment are known. For example, by using another carbon based material such as graphene large increases in EUV reflection (which may result from other materials) may be avoided. Furthermore, other materials may have an increased susceptibility to the hydrogen etching within the lithographic apparatus.

The two-dimensional material may comprise hexagonal boron nitride (h-BN).

The two-dimensional material may comprise molybdenum disulfide (MoS2).

Advantageously, these materials (h-BN and MoS2) are robust against hydrogen etching and therefore for embodiments wherein the two-dimensional material comprises hexagonal boron nitride (h-BN) and/or molybdenum disulfide (MoS2) a capping layer having a smaller thickness may be applied.

In some embodiments, at least one layer of two-dimensional material may be provided adjacent to both sides of the porous membrane and a capping layer may be provided on each side of the membrane such that the at least one layer of two-dimensional material is disposed between a capping layer and the porous membrane.

It will be appreciated that different types of two-dimensional material may be provided on different sides of the porous membrane.

The or each capping layer may be a three-dimensional material.

Advantageously, three-dimensional materials are significantly easier to manufacture than two-dimensional materials. As discussed above, the two-dimensional material effectively closes the structure of the porous membrane. This allows three-dimensional materials to be used for the capping layer whilst enjoying the benefits of the pellicle according to the second aspect, as discussed above.

The at least one capping layer may be suitable to protect the porous layer and the at least one layer of two-dimensional material from hydrogen etching.

It will be appreciated that in order to be suitable to protect the other two layers from hydrogen etching, the capping layer (a) may be formed from a suitable material that is not strongly etched by hydrogen; and (b) may have a suitable thickness. Example materials are discussed below.

The at least one capping layer may be formed from a material having an extinction coefficient for EUV radiation of less than 0.02 nm⁻¹.

It is desirable to minimize the absorption of EUV radiation by the membrane.

Therefore, it is generally desirable to form the capping layer from a material having the smallest extinction coefficient for EUV radiation possible.

In some embodiments, the capping layer is formed from a material having an extinction coefficient for EUV radiation of less than 0.01 nm⁻¹. In some embodiments, the capping layer is formed from a material having an extinction coefficient for EUV radiation of less than 0.005 nm⁻¹.

The capping layer may have a thickness of the order of 0.3 to 5 nm.

The capping layer may comprise yttrium or yttrium oxide.

The capping layer may comprise any of the following: aluminium oxide (Al₂O₃), hafnium oxide (HfO₂), zirconium oxide (ZrO₂), ruthenium (Ru), platinum (Pt), gold (Au), zirconium nitride (ZrN), aluminium (Al) or zirconium (Zr).

The capping layer may comprise a plurality of sublayers formed from different materials.

The lithographic apparatus may further comprise a membrane border at a periphery of the porous membrane.

According to a fourth aspect of the present disclosure there is provided a pellicle for use in a lithographic apparatus, the pellicle comprising: a membrane; a border at a periphery of, and on a first side of, the membrane; and a protective portion at a periphery of, and on a second side of, the membrane.

The pellicle may be suitable for use adjacent to a reticle within an EUV lithographic apparatus. The pellicle according to the fourth aspect is particularly advantageous, as now discussed.

As discussed above, the presence of low pressure hydrogen gas within a lithographic apparatus can etch pellicles, limiting the potential lifetime of the pellicle. In order to mitigate such etching of pellicles, it has previously been proposed to provide pellicles with a protecting, capping layer. However, it is desirable to minimize the absorption of EUV radiation by the pellicle and therefore the materials and thicknesses of such capping layers are typically rather limited.

The inventors of the present invention have realized that the etching of carbon by hydrogen ions and free radicals is temperature dependent. In particular, the inventors have realized that the carbon etching rate is higher at low and intermediate temperatures but the carbon etching rate falls to a negligible level at sufficiently high temperatures. The inventors have also realized that whilst a central portion of a pellicle within an EUV lithographic scanner may reach a sufficiently high temperature that hydrogen etching will be negligible (at least part of the time), a periphery of the pellicle will typically remain below this temperature and will therefore be more susceptible to hydrogen etching.

Advantageously, the pellicle according to the fourth aspect provides an additional protective portion on a portion of (a front side of) the membrane that: (a) is most at risk from hydrogen etching; and (b) in use, does not receive EUV radiation. This allows the lifetime of the pellicle to be increased without effecting the performance of the lithographic apparatus.

The protective portion may be provided on a portion of the membrane that, in use, does not receive EUV radiation.

The protective portion may be provided on a portion of the membrane that coincides with the border.

That is, the protective portion overlaps with the border (but is provided on the opposite side of the pellicle).

The protective portion may extend partially into a portion of the membrane that does not coincide with the border.

That is, the protective portion may also extend partially inwards onto a region of the membrane that is not attached to the border.

The protective portion may be formed from the same material as a bulk of the membrane.

For such embodiments, the protective portion may be an increased thickness of the bulk material (for example a CNT membrane), which may act as a sacrificial portion providing an increased thickness to be etched by the hydrogen.

Additionally or alternatively, the protective portion may comprise a material that is suitable to protect a portion of the membrane to which it is attached from hydrogen etching.

For such embodiments, the protective portion comprises a capping material. It will be appreciated that a greater thickness of such a capping material may be provided in the protective portion (relative to a central portion of the membrane).

The membrane may comprise nanotubes, graphene and/or amorphous carbon.

For example, the membrane may be a fabric formed from CNTs. This may be referred to as a carbon nanotube membrane. This is a particularly promising material for use as a pellicle membrane in an EUV lithographic apparatus. Such a CNT pellicle is a porous material and, therefore, can provide very high EUV transmission (of >98%). Furthermore, CNT pellicles also provide very good mechanical stability and can therefore be manufactured at small thicknesses, whilst remaining robust against mechanical failure.

The pellicle may further comprise a capping material coating at least one surface of the membrane.

The capping material may comprise any of the following materials either alone or in combination: yttrium (Y), yttrium oxide (YₐO_{b}), aluminium oxide (Al₂O₃), hafnium oxide (HfO₂), zirconium oxide (ZrO₂), ruthenium (Ru), platinum (Pt), gold (Au), zirconium nitride (ZrN), aluminium (Al) or zirconium (Zr). The capping material may comprise a plurality of sublayers formed from different materials.

It will be appreciated that the second and fourth aspects of the present disclosure may be combined.

In particular, the membrane of the pellicle according to the fourth aspect may comprise: a porous membrane formed from a first material; at least one layer of two-dimensional material adjacent at least one side of the porous membrane; and at least one capping layer adjacent the at least one layer of two-dimensional material such that the at least one layer of two-dimensional material is disposed between the or each capping layer and the porous membrane.

It will be appreciated that one or more aspects or features described above or referred to in the following description may be combined with one or more other aspects or features.

### BRIEF DESCRIPTION OF THE DRAWINGS

Embodiments of the invention will now be described, by way of example only, with reference to the accompanying schematic drawings, in which:

FIG. 1 is a schematic illustration of a lithographic system comprising a lithographic apparatus and a radiation source;

FIG. 2 is a schematic illustration of a method for forming a pellicle according to an embodiment of the present disclosure;

FIG. 3A is a schematic illustration of a first embodiment of the method shown in FIG. 2;

FIG. 3B is a schematic illustration of a second embodiment of the method shown in FIG. 2;

FIG. 4 is a schematic representation of a method of applying a graphene film to both sides of a CNT membrane;

FIG. 5 shows a schematic cross section of a pellicle according to an embodiment of the present disclosure; and

FIG. 6 shows an expected etching rate for hydrogen etching of carbon as a function of temperature for a hydrogen ion flux of 1.5·10¹⁹ m⁻²·s⁻¹ for four different ion energies: 5 eV, 10 eV, 20 eV and 30 eV; FIG. 6 also shows an sp3 carbon concentration as a function of temperature.

### DETAILED DESCRIPTION

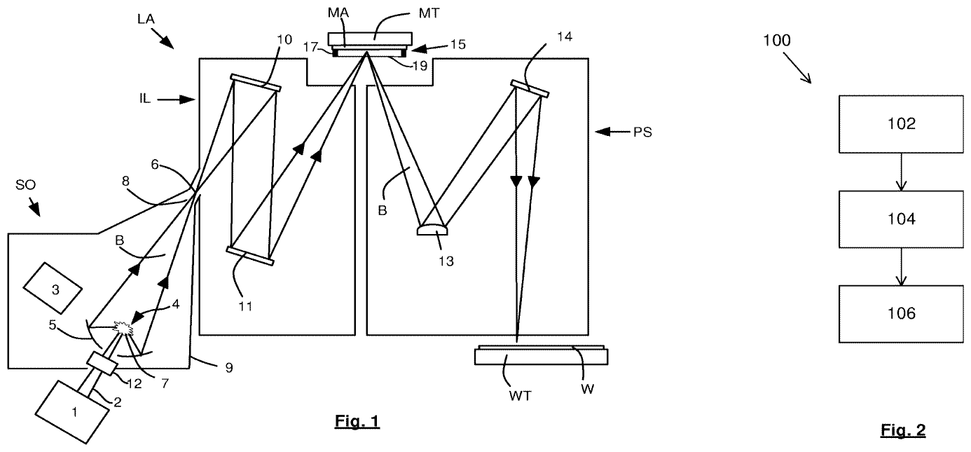

FIG. 1 shows a lithographic system. The lithographic system comprises a radiation source SO and a lithographic apparatus LA. The radiation source SO is configured to generate an extreme ultraviolet (EUV) radiation beam B. The lithographic apparatus LA comprises an illumination system IL, a support structure MT configured to support a reticle assembly 15 including a patterning device MA (e.g., a reticle or mask), a projection system PS and a substrate table WT configured to support a substrate W. The illumination system IL is configured to condition the radiation beam B before it is incident upon the patterning device MA. The projection system is configured to project the radiation beam B (now patterned by the patterning device MA) onto the substrate W. The substrate W may include previously formed patterns. Where this is the case, the lithographic apparatus aligns the patterned radiation beam B with a pattern previously formed on the substrate W.

The radiation source SO, illumination system IL, and projection system PS may all be constructed and arranged such that they can be isolated from the external environment. A gas at a pressure below atmospheric pressure (e.g., hydrogen) may be provided in the radiation source SO. A vacuum may be provided in the illumination system IL and/or the projection system PS. A small amount of gas (e.g., hydrogen) at a pressure well below atmospheric pressure may be provided in the illumination system IL and/or the projection system PS.

The radiation source SO shown in FIG. 1 is of a type that may be referred to as a laser produced plasma (LPP) source. A laser 1, which may for example be a CO₂ laser, is arranged to deposit energy via a laser beam 2 into a fuel, such as tin (Sn) that is provided from a fuel emitter 3. Although tin is referred to in the following description, any suitable fuel may be used. The fuel may for example be in liquid form, and may for example be a metal or alloy. The fuel emitter 3 may comprise a nozzle configured to direct tin, e.g., in the form of droplets, along a trajectory towards a plasma formation region 4. The laser beam 2 is incident upon the tin at the plasma formation region 4. The deposition of laser energy into the tin creates a plasma 7 at the plasma formation region 4. Radiation, including EUV radiation, is emitted from the plasma 7 during de-excitation and recombination of ions of the plasma.

The EUV radiation is collected and focused by a near normal incidence radiation collector 5 (sometimes referred to more generally as a normal incidence radiation collector). The collector 5 may have a multilayer structure that is arranged to reflect EUV radiation (e.g., EUV radiation having a desired wavelength such as 13.5 nm). The collector 5 may have an elliptical configuration, having two ellipse focal points. A first focal point may be at the plasma formation region 4, and a second focal point may be at an intermediate focus 6, as discussed below.

In other embodiments of a laser produced plasma (LPP) source the collector 5 may be a so-called grazing incidence collector that is configured to receive EUV radiation at grazing incidence angles and focus the EUV radiation at an intermediate focus. A grazing incidence collector may, for example, be a nested collector, comprising a plurality of grazing incidence reflectors. The grazing incidence reflectors may be disposed axially symmetrically around an optical axis.

The radiation source SO may include one or more contamination traps (not shown). For example, a contamination trap may be located between the plasma formation region 4 and the radiation collector 5. The contamination trap may for example be a rotating foil trap, or may be any other suitable form of contamination trap.

The laser 1 may be separated from the radiation source SO. Where this is the case, the laser beam 2 may be passed from the laser 1 to the radiation source SO with the aid of a beam delivery system (not shown) comprising, for example, suitable directing mirrors and/or a beam expander, and/or other optics. The laser 1 and the radiation source SO may together be considered to be a radiation system.

Radiation that is reflected by the collector 5 forms a radiation beam B. The radiation beam B is focused at point 6 to form an image of the plasma formation region 4, which acts as a virtual radiation source for the illumination system IL. The point 6 at which the radiation beam B is focused may be referred to as the intermediate focus. The radiation source SO is arranged such that the intermediate focus 6 is located at or near to an opening 8 in an enclosing structure 9 of the radiation source SO.

The radiation beam B passes from the radiation source SO into the illumination system IL, which is configured to condition the radiation beam. The illumination system IL may include a facetted field mirror device 10 and a facetted pupil mirror device 11. The faceted field mirror device 10 and faceted pupil mirror device 11 together provide the radiation beam B with a desired cross-sectional shape and a desired angular distribution. The radiation beam B passes from the illumination system IL and is incident upon the reticle assembly 15 held by the support structure MT. The reticle assembly 15 includes a patterning device MA and a pellicle 19. The pellicle is mounted to the patterning device MA via a pellicle frame 17. The reticle assembly 15 may be referred to as a reticle and pellicle assembly 15. The patterning device MA reflects and patterns the radiation beam B. The illumination system IL may include other mirrors or devices in addition to or instead of the faceted field mirror device 10 and faceted pupil mirror device 11.

Following reflection from the patterning device MA the patterned radiation beam B enters the projection system PS. The projection system comprises a plurality of mirrors 13, 14 that are configured to project the radiation beam B onto a substrate W held by the substrate table WT. The projection system PS may apply a reduction factor to the radiation beam, forming an image with features that are smaller than corresponding features on the patterning device MA. A reduction factor of 4 may for example be applied. Although the projection system PS has two mirrors 13, 14 in FIG. 1, the projection system PS may include any number of mirrors (e.g., six mirrors).

The lithographic apparatus may, for example, be used in a scan mode, wherein the support structure (e.g., mask table) MT and the substrate table WT are scanned synchronously while a pattern imparted to the radiation beam is projected onto a substrate W (i.e., a dynamic exposure). The velocity and direction of the substrate table WT relative to the support structure (e.g., mask table) MT may be determined by the demagnification and image reversal characteristics of the projection system PS. The patterned radiation beam that is incident upon the substrate W may comprise a band of radiation. The band of radiation may be referred to as an exposure slit. During a scanning exposure, the movement of the substrate table WT and the support structure MT may be such that the exposure slit travels over an exposure field of the substrate W.

The radiation source SO and/or the lithographic apparatus that is shown in FIG. 1 may include components that are not illustrated. For example, a spectral filter may be provided in the radiation source SO. The spectral filter may be substantially transmissive for EUV radiation but substantially blocking for other wavelengths of radiation such as infrared radiation.

In other embodiments of a lithographic system the radiation source SO may take other forms. For example, in alternative embodiments the radiation source SO may comprise one or more free electron lasers. The one or more free electron lasers may be configured to emit EUV radiation that may be provided to one or more lithographic apparatus.

As was described briefly above, the reticle assembly 15 includes a pellicle 19 that is provided adjacent to the patterning device MA. The pellicle 19 is provided in the path of the radiation beam B such that radiation beam B passes through the pellicle 19 both as it approaches the patterning device MA from the illumination system IL and as it is reflected by the patterning device MA towards the projection system PS. The pellicle 19 comprises a thin film or membrane that is substantially transparent to EUV radiation (although it will absorb a small amount of EUV radiation). By EUV transparent pellicle or a film substantially transparent for EUV radiation herein is meant that the pellicle 19 is transmissive for at least 65% of the EUV radiation, preferably at least 80% and more preferably at least 90% of the EUV radiation. The pellicle 19 acts to protect the patterning device MA from particle contamination.

Whilst efforts may be made to maintain a clean environment inside the lithographic apparatus LA, particles may still be present inside the lithographic apparatus LA. In the absence of a pellicle 19, particles may be deposited onto the patterning device MA. Particles on the patterning device MA may disadvantageously affect the pattern that is imparted to the radiation beam B and therefore the pattern that is transferred to the substrate W. The pellicle 19 advantageously provides a barrier between the patterning device MA and the environment in the lithographic apparatus LA in order to prevent particles from being deposited on the patterning device MA.

The pellicle 19 is positioned at a distance from the patterning device MA that is sufficient that any particles that are incident upon the surface of the pellicle 19 are not in a field plane of the lithographic apparatus LA. This separation between the pellicle 19 and the patterning device MA acts to reduce the extent to which any particles on the surface of the pellicle 19 impart a pattern to the radiation beam B that is imaged onto the substrate W. It will be appreciated that where a particle is present in the beam of radiation B, but at a position that is not in a field plane of the beam of radiation B (for example not at the surface of the patterning device MA), then any image of the particle will not be in focus at the surface of the substrate W. In the absence of other considerations it may be desirable to position the pellicle 19 a considerable distance away from the patterning device MA. However, in practice the space which is available in the lithographic apparatus LA to accommodate the pellicle is limited due to the presence of other components. In some embodiments, the separation between the pellicle 19 and the patterning device MA may, for example, be approximately between 1 mm and 10 mm, for example between 1 mm and 5 mm, for example between 2 mm and 2.5 mm.

The pellicle may comprise a border portion and a membrane. The border portion of the pellicle may be hollow and generally rectangular and the membrane may be bounded by the border portion. As known in the art, one type of pellicle may be formed by deposition of one or more thin layers of material on a generally rectangular silicon substrate. The silicon substrate supports the one or more thin layers during this stage of the construction of the pellicle. Once a desired or target thickness and composition of layers has been applied, a central portion of the silicon substrate is removed by etching (this may be referred to as back etching). A peripheral portion of the rectangular silicon substrate is not etched (or alternatively is etched to a lesser extent than the central portion). This peripheral portion forms the border portion of the final pellicle while the one or more thin layers form the membrane of the pellicle (which is bordered by the border portion). The border portion of the pellicle may be formed from silicon.

Some embodiments of the present disclosure relate to a new type of pellicle and methods of forming such a pellicle.

A pellicle (for example comprising a membrane and a border) may require some support from a more rigid pellicle frame. The pellicle frame may provide two functions. First, the pellicle frame may support the pellicle and may also tension the pellicle membrane. Second, the pellicle frame may facilitate connection of the pellicle to a patterning device (reticle). It one known arrangement, the pellicle frame may comprise a main, generally rectangular body portion which is glued to the border portion of the pellicle and titanium attachment mechanisms that are glued to the side of this main body. Intermediate fixing members (known as studs) are affixed to the patterning device (reticle). The intermediate fixing members (studs) on the patterning device (reticle) may engage (for example releasably engage) with the attachment members of the pellicle frame.

Some embodiments of the present disclosure relate to a method of forming a pellicle for use in a lithographic apparatus such as the lithographic apparatus LA shown in FIG. 1. Such a method 100 is illustrated schematically in FIG. 2.

The method 100 comprises a step 102 of providing a porous membrane formed from a first material. It will be appreciated that as used here a porous membrane is intended to mean a material with an open structure such as, for example, a nanotube membrane. In some embodiments, the porous membrane may comprise a nanostructure. In some embodiments, the porous membrane may comprise nanotubes. For example, the porous membrane may be a fabric formed from CNTs. This may be referred to as a carbon nanotube membrane.

The method 100 further comprises a step 104 of applying at least one layer of two-dimensional material to at least one side of the porous membrane.

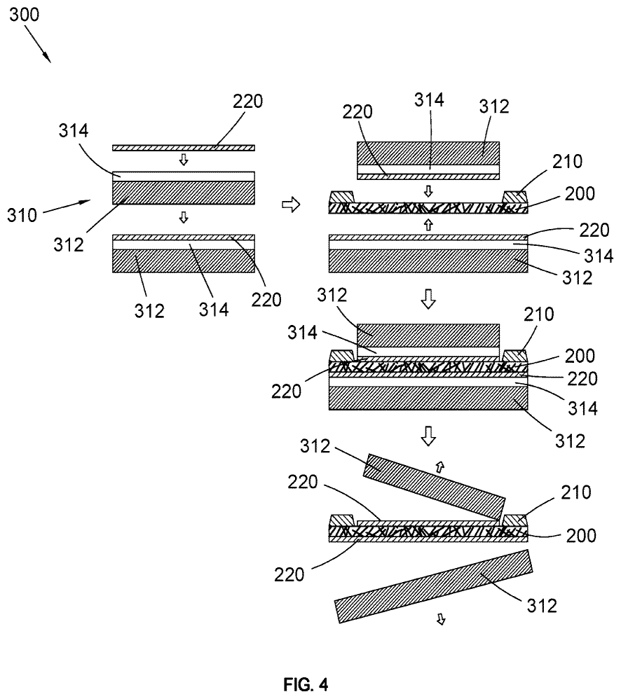

In some embodiments, the or each at least one layer of two-dimensional material is applied as a substantially continuous layer adjacent the at least one side of the porous membrane. This may be applied using a wet transfer method. Alternatively, the or each at least one layer of two-dimensional material may be transferred from a temporary or intermediate support substrate, as discussed further below with reference to FIG. 4.

It will be appreciated that as used here a two-dimensional material is intended to mean a material formed from one or more single atom layers such as, for example, graphene. It will be appreciated that various different two-dimensional materials may be used.

In some embodiments, the two-dimensional material may comprise graphene. In some embodiments 3 layers of graphene may be provided adjacent one or both sides of the porous membrane. In one embodiment, the porous membrane may be a carbon nanotube membrane and the two-dimensional material comprises graphene. A single layer of graphene may have a thickness of the order of 0.35 nm. A distance between two stacked layers of graphene may be of the order of 0.14 nm. Therefore, a thickness of 3 layers of graphene may be of the order of 1.3 nm.

One benefit of using graphene as the two-dimensional material is that pellicles have previously been formed from carbon and the properties of carbon in this environment are known. For example, by using another carbon based material such as graphene large increases in EUV reflection (which may result from other materials) may be avoided. Furthermore, other materials may have an increased susceptibility to the hydrogen etching within the lithographic apparatus.

Alternatively or in addition, in some embodiments, the two-dimensional material may comprise hexagonal boron nitride (h-BN). Alternatively or in addition, in some embodiments, the two-dimensional material may comprise molybdenum disulfide (MoS2). Advantageously, these materials (h-BN and MoS2) are robust against hydrogen etching and therefore for embodiments wherein the two-dimensional material comprises hexagonal boron nitride (h-BN) and/or molybdenum disulfide (MoS2) a capping layer having a smaller thickness may be applied in subsequent steps. A single layer of hexagonal boron nitride (h-BN) or molybdenum disulfide (MoS2) may have a thickness of the order of 0.65 nm.

In some embodiments, the or each at least one layer of two-dimensional material has a thickness of the order of 0.5 nm to 5 nm. In some embodiments, the or each at least one layer of two-dimensional material has a thickness of the order of 0.5 nm to 2 nm.

The method 100 further comprises a step 106 of applying a capping layer to the at least one layer of two-dimensional material on at least one side of the porous membrane such that the at least one layer of two-dimensional material is disposed between the or each capping layer and the porous membrane.

In some embodiments the or each capping layer may be a three-dimensional material. Advantageously, three-dimensional materials are significantly easier to manufacture than two-dimensional materials. As discussed below, the two-dimensional material (provided at step 104) effectively closes the structure of the porous membrane. This allows three-dimensional materials to be used for the capping layer whilst enjoying the benefits of the method 100 of FIG. 2, as discussed below.

It will be appreciated that unless otherwise stated, herein a total EUV transmissivity of the capping layer is intended to mean the percentage of EUV radiation that is transmitted after propagating through the pellicle. For embodiments wherein a capping layer is provided on each side of the pellicle the total EUV transmissivity of the capping layers means the total transmissivity from both sides.

In some embodiments, a total EUV transmissivity of the or each capping layer is 96% or more. In some embodiments, the total EUV transmissivity of the at least one capping layer may be 96.5% or more. In some embodiments, the total EUV transmissivity of the at least one capping layer may be 97% or more. In some embodiments, the total EUV transmissivity of the at least one capping layer may be 97.5% or more. In some embodiments, the total EUV transmissivity of the at least one capping layer be of the order of 97.8%.

It will be appreciated that the EUV transmissivity of the capping layer is, in general, dependent on (a) the type of material(s) from which the capping layer is formed; and (b) a thickness of the capping layer. It will be appreciated that the EUV transmissivity of the capping layer is, in general, also dependent on a density or porosity of the capping layer. Example materials are discussed below.

In some embodiments, the at least one capping layer is formed from a material suitable to protect the porous layer and the at least one layer of two-dimensional material from hydrogen etching. It will be appreciated that in order to be suitable to protect the other two layers from hydrogen etching, the capping layer (a) may be formed from a suitable material that is not strongly etched by hydrogen; and (b) may have a suitable thickness. Example materials are discussed below.

It is desirable to minimize the absorption of EUV radiation by the pellicle. Therefore, it is generally desirable to form the capping layer from a material having the smallest extinction coefficient for EUV radiation possible.

In some embodiments, the at least one capping layer may be formed from a material having an extinction coefficient for EUV radiation of less than 0.02 nm⁻¹. In some embodiments, the capping layer is formed from a material having an extinction coefficient for EUV radiation of less than 0.01 nm⁻¹. In some embodiments, the capping layer is formed from a material having an extinction coefficient for EUV radiation of less than 0.005 nm⁻¹.

In some embodiments, the capping layer may have a thickness of the order of 0.3 to 5 nm. That is, the capping layer may have a thickness as small as one monolayer of atoms (i.e. a thickness of 0 or 1 atoms and having an interatomic distance of, for example, of the order of 0.3 nm). In other embodiments, the capping layer may have a larger thickness to provide better protection of the underlying layers of two-dimensional material and the porous membrane. In some embodiments, the capping layer may have a thickness of more than 1 nm. In some embodiments, the capping layer may have a thickness of more than 1.5 nm. In some embodiments, the capping layer may have a thickness of more than 2 nm. In some embodiments, the capping layer may have a thickness of more than 5 nm.

In some embodiments, the capping layer comprises yttrium (Y) or yttrium oxide (YₐO_{b}). Yttrium has an extinction coefficient for EUV radiation of the order of 0.0021 nm⁻¹. Yttrium oxide (Y₂O₃) has an extinction coefficient for EUV radiation of the order of 0.01 nm⁻¹. Therefore, for embodiments wherein there is a 1.5 nm thickness capping layer of yttrium oxide (Y₂O₃) on each side of the pellicle membrane a total EUV transmissivity of the at least one capping layer is around 97%.

In some embodiments, the step 106 of applying the capping layer to the at least one layer of two-dimensional material on at least one side of the porous membrane may comprise applying a plurality of sublayers, each sublayer comprising a different material. For example, in some embodiments, the step 106 of applying the capping layer to the at least one layer of two-dimensional material on at least one side of the porous membrane comprises: applying a first sublayer of a first material to the at least one layer of two-dimensional material on at least one side of the porous membrane; and applying a second sublayer of a second material to the first sublayer. The first sublayer may have a smaller extinction coefficient for EUV radiation than the second sublayer. The second (outermost) sublayer may have improved chemical stability than the first sublayer. In some embodiments, the first sublayer may comprise a metal and the second sublayer may comprise a metal oxide.

In some embodiments, the porous membrane may be substantially self-supporting. It will be appreciated that, in use, a pellicle will be supported around its periphery by a pellicle frame, which is mounted to a reticle or mask MA. As used here, the porous membrane being substantially self-supporting is intended to mean that the porous membrane supports its own weight. That is, there is no additional membrane adjacent the porous membrane providing support for the porous membrane, other than the at least one layer of two-dimensional material and the capping layer.

It will be appreciated that a non-porous membrane may have two generally parallel surfaces that define two opposed sides of the membrane. A volume bounded by the two generally parallel surfaces is substantially occupied by the material from which the non-porous membrane is formed. It will be further appreciated that, in contrast, a porous membrane comprises regions which are occupied by a material from which the porous membrane is formed interspersed with voids which have no material. For such a porous membrane two generally parallel imaginary or non-physical surfaces may define the boundaries or sides of the membrane. The volume bounded by the two generally parallel imaginary surfaces is only partially occupied by the material from which the porous membrane is formed. Applying at least one layer of two-dimensional material to at least one side of the porous membrane is intended to include applying the at least one layer of two-dimensional material to at least one imaginary or non-physical surface that defines a boundary or side of the porous membrane.

A thickness of the porous membrane may be defined as a distance between two generally parallel imaginary or non-physical surfaces that define the boundaries or sides of the membrane. The porous membrane may have a thickness of the order of 1-100 nm. The porous membrane may have a thickness of the order of 10-100 nm. The porous membrane may have a thickness of the order of 50-100 nm. In some embodiments, the porous membrane may be considered to form a majority of the thickness of the pellicle.

In some embodiments, the method 100 shown in FIG. 2 may further comprising attaching a pellicle border to a periphery of the porous membrane. For such embodiments, the pellicle border may be attached to the periphery of the porous membrane before the at least one layer of two-dimensional material is applied to at least one side of the porous membrane (at step 104).

The method 100 shown in FIG. 2 is particularly advantageous, as now discussed. The at least one layer of two-dimensional material acts to close the adjacent side of the porous membrane.

The method 100 shown in FIG. 2 results in a pellicle wherein a bulk of the pellicle is formed from a porous material. Advantageously, this can result in a pellicle with a reduced density and, therefore, an increased transmissivity for extreme ultraviolet (EUV) radiation. This is particularly important for EUV lithography systems and improves throughput of the system. One particularly promising material for use as a pellicle membrane in an EUV lithographic apparatus is a fabric or membrane formed from carbon nanotubes (CNTs). Such a CNT pellicle is a porous material and, therefore, can provide very high EUV transmission (of >98%). Furthermore, CNT pellicles also provide very good mechanical stability and can therefore be manufactured at small thicknesses, whilst remaining robust against mechanical failure. However, a low pressure hydrogen gas is typically provided within the lithographic apparatus, which forms a hydrogen plasma in the presence of the EUV radiation (during exposure). It has been found that hydrogen ions and hydrogen free radicals from the hydrogen plasma can etch pellicles formed from CNTs, limiting the potential lifetime of the pellicle and blocking commercial implementation of CNT pellicles.

In order to mitigate such etching of CNT pellicles, it has previously been proposed to provide such CNT pellicles with a protective, capping layer. Such a capping layer may be formed from a material which is chemically stable in the environment of the lithographic apparatus and which has a low extinction coefficient for EUV radiation.

However, a difference between the refractive indices of carbon and suitable capping layers is typically larger than a difference between the refractive indices of carbon and the vacuum. Therefore, the inventors have realized that such a capping layer will result in an increase in EUV flare, which is undesirable. Applying at least one layer of two-dimensional material to the porous membrane (at step 104) and then subsequently applying a capping layer to the at least one layer of two-dimensional material (at step 106) is particularly advantageous, as now discussed.

It will be appreciated that a porous material will have a structure and therefore if there is a large contrast between the refractive index of the porous material and the surrounding medium, as radiation (for example EUV radiation) propagates through the pellicle the radiation will be scattered (for example via Mie scattering). This will lead to undesirable diffusion or flare of the radiation, again impacting on the imaging performance of the lithographic apparatus LA. Since EUV radiation is so strongly absorbed by most materials, EUV lithographic systems are typically operated at high vacuum. Therefore, it may be particularly desirable for the porous material to be formed from material having a refractive index close to 1. It may also be desirable for the porous material to be formed from a material having an extinction coefficient for EUV radiation which is as low as possible.

The at least one layer of two-dimensional material (applied at step 104 of the method 100 shown in FIG. 2) acts to close the adjacent side of the porous membrane and to form a smoother and flatter exterior surface of the pellicle. This allows for the capping layer to be provided over said smoother and flatter exterior surface. Advantageously, this allows the porous membrane to be protected from etching whilst reducing EUV flare, regardless of the material used for the capping layer. Furthermore, in addition to being significantly smoother and flatter than a surface of the porous material, the surface of the two dimensional material will have a smaller surface area. As a result, when a (relatively thin) capping layer is provided on the two dimensional material rather than directly on the porous material, a volume of the capping layer is reduced. Advantageously, this also results in a higher EUV transmissivity of the pellicle for the same thickness of capping layer.

Within a CNT membrane the carbon nanotubes may be separate or, alternatively, they may clump together in bundles. Furthermore, the size of such bundles may vary. It has been found by the inventors that when a capping layer is applied directly to a CNT membrane, the loss of EUV transmissivity due to a capping layer is strongly dependent on an extent of bundling within the CNT membrane. For example, for a fixed density of CNTs in the membrane, the smaller the number of CNTs per bundle, the larger the loss of EUV transmissivity will be. Advantageously, by using the method 100 shown in FIG. 2, since the capping layer is applied (in step 106) to the at least one layer of two-dimensional material (rather than the porous membrane) the loss of EUV transmissivity is no longer dependent in the typical size of structures within the porous membrane (for example the amount of bundling in the case of a CNT membrane). In fact, by applying it to the flat layers of two-dimensional, for a given thickness of capping layer the loss of EUV transmissivity is minimized.

Finally, the at least one layer of two-dimensional material of the pellicle formed using the method 100 shown in FIG. 2 closes the structure of the porous layer. Advantageously, this results in a higher particle stopping power than a CNT pellicle without such layers of two-dimensional material.

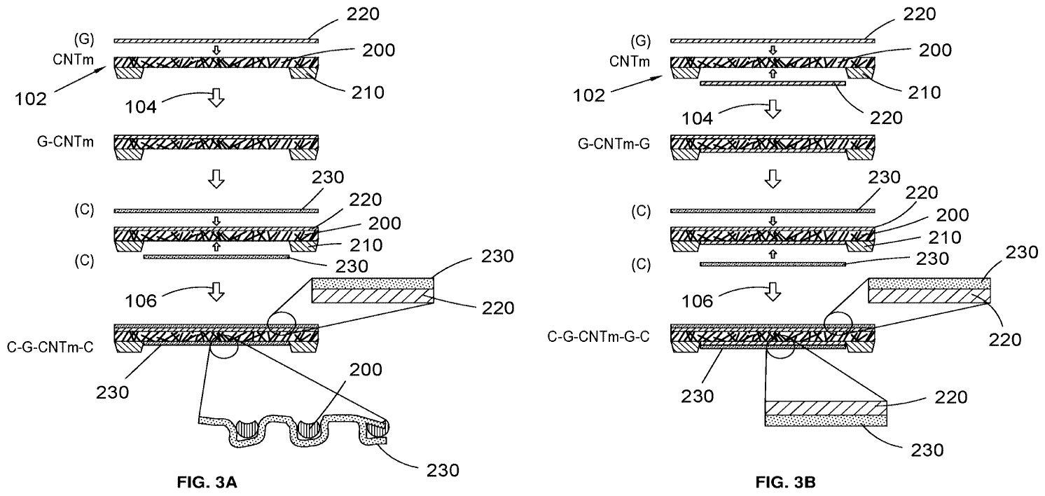

Two example embodiments of the general method 100 shown schematically in FIG. 2 are now described with reference to FIGS. 3A and 3B.

FIG. 3A is a schematic illustration of a first embodiment of the method 100 shown in FIG. 2. The method comprises providing a porous membrane 200 formed from CNTs. This may be referred to as a carbon nanotube membrane or CNTm. The porous membrane 200 is mounted on a pellicle border 210 at a periphery of the porous membrane. The pellicle border 210 may comprise a generally rectangular frame. The pellicle border 210 may, for example, be formed from silicon, which is used for conventional non-porous membranes. Alternatively, the pellicle border 210 may, for example, be formed from carbon nanotubes, quartz or steel, which materials may provide additional benefits. The porous membrane 200 may have been previously attached to the pellicle border 210 using known techniques.

The EUV transmissivity of the porous CNT membrane 210 may be around 97.5%. The porous CNT membrane 210 may have a thickness of the order of 100 nm. The following example embodiments are based on a porous CNT membrane 210 having an EUV transmissivity of around 97.5% and a thickness of the order of 100 nm.

As explained above, a thickness of a porous membrane may be defined as a distance between two generally parallel imaginary or non-physical surfaces that define the boundaries or sides of the membrane. As also explained above, the volume bounded by the two generally parallel imaginary surfaces is only partially occupied by the material from which the porous membrane is formed (the porous membrane comprising regions which are occupied by material interspersed with voids which have no material). To give some idea of how porous the example porous CNT membrane 210 is, based on the extinction coefficient of carbon for EUV radiation, in order to achieve a traditional non-porous membrane formed from carbon having an EUV transmissivity of around 97.5%, the non-porous membrane would have a thickness of the order of 4 nm. In contrast, the example porous CNT membrane 210 has a thickness of the order of 100 nm.

The method comprises providing a graphene film 220. For example, the graphene film 220 may comprise a single graphene layer or a three graphene layer (3GL) although it will be appreciated that the graphene film 220 may comprise any number of graphene layers. In general, the graphene film 220 comprises least one layer of two-dimensional material. The EUV transmissivity of the graphene film 220 for a single graphene layer may be around 99.8%. The EUV transmissivity of the graphene film 220 (for a three graphene layer) may be around 99.5%.

The method further comprises a step 104 of applying the graphene film 220 to a side of the porous membrane 200. In this embodiment, the graphene film 220 is applied to a side which is opposite, or distal from, the side to which the pellicle border 210 is attached. In this embodiment, the graphene film 220 is applied as a substantially continuous layer adjacent the side of the porous membrane 200. The graphene film 220 may be applied using a wet transfer method. Alternatively, the graphene film 220 may be transferred from a temporary or intermediate support substrate, as discussed further below with reference to FIG. 4. The combination of the porous CNT membrane 200 and the graphene film 220 may be referred to as G-CNTm. The EUV transmissivity of the porous CNT membrane 200 with the graphene film 220 (for a single graphene layer) may be around 97.3%.

The method further comprises a step 106 of applying a capping layer 230 to the graphene film 220 such that the graphene film 220 is disposed between the capping layer 230 and the porous membrane 200. Although shown schematically as a layer of material being formed and then applied to the graphene film 220 it will be appreciated that, in practice, the capping layer 230 may be formed on the graphene film 220 (i.e. formed in situ).

In this embodiment, the method further comprises applying a capping layer 230 to a second side of the porous membrane 200. In particular, the capping layer 230 is applied to the same side to which the pellicle border 210 is attached.

In some embodiments, the capping layer 230 comprises yttrium oxide (Y₂O₃). Therefore, in some embodiments, the step 106 of applying the capping layer 230 to the graphene film 220 comprises: applying a layer of yttrium oxide (Y₂O₃) either directly to the graphene film 220 or to an intermediate sublayer. For example, in one embodiment the capping layer comprises a layer of yttrium oxide (Y₂O₃) having a thickness of 1.5 nm.

The graphene film 220 acts to close the adjacent side of the porous membrane 200 and to form a smoother and flatter exterior surface of the pellicle. This can be seen from a comparison of the schematic enlarged portion of the interfaces with the two capping layers 230. This allows for the capping layer 230 applied to the graphene film 220 to be provided over said smoother and flatter exterior surface. Advantageously, this allows the porous membrane 200 to be protected from etching whilst reducing EUV flare, regardless of the material used for the capping layer 230.

Furthermore, in addition to being significantly smoother and flatter than a surface of the porous material 200, the surface of the graphene film 220 will have a smaller surface area. As a result, when a (relatively thin) capping layer 230 is provided on the graphene film 220 rather than directly on the porous membrane 200, a volume of the capping layer 230 is reduced. Again, this can be seen from a comparison schematic enlarged portions of the interfaces with the two capping layers 230. Advantageously, this also results in a higher EUV transmissivity of the pellicle for the same thickness of capping layers 230.

The graphene film 220 closes the structure of the porous membrane 200, which, advantageously, results in a higher particle stopping power than a CNT pellicle without such a graphene film 220.

In this embodiment as shown in FIG. 3A, the capping layer 230 on the cavity side of the pellicle (i.e. on the same side as the pellicle border 210) has undulations since there the cap is deposited directly on porous membrane 200. Although this may be disadvantageous for EUV transmission non-uniformity and flare reduction, it may be beneficial for EUV reflection.

In some embodiments of the method 100 shown in FIG. 2, in step 104, at least one layer of two-dimensional material may be applied to both sides of the porous membrane and a capping layer may be applied on each side of the pellicle such that the at least one layer of two-dimensional material is disposed between each capping layer and the porous membrane. An example of such an embodiment of the method 100 for forming a pellicle is now described with reference to FIG. 3B.

FIG. 3B is a schematic illustration of a second embodiment of the method 100 shown in FIG. 2. The embodiment of the method shown in FIG. 3B is very similar to the embodiment of the method shown in FIG. 3A. Therefore, in the following only the differences will be explained in detail.

The embodiment of the method shown in FIG. 3B comprises providing two graphene films 220. The graphene films may be substantially as the single graphene film described above with reference to FIG. 3B.

In the embodiment of the method shown in FIG. 3B, the method comprises a step 104 of applying the two graphene films 220 to opposite sides of the porous membrane 200. That is, in this embodiment, the graphene film 220 is applied to each of: the side to which the pellicle border 210 is attached and the opposite side. Again, in this embodiment, the graphene films 220 are each applied as a substantially continuous layer adjacent a side of the porous membrane 200. The combination of the porous CNT membrane 200 and the two graphene films 220 may be referred to as G-CNTm-G. The EUV transmissivity of the porous CNT membrane 200 with the two graphene films 220 (with each film comprising a single graphene layer) is around 97.1%.

The embodiment of the method shown in FIG. 3B comprises a step 106 of applying a capping layer 230 to each of the two graphene films 220 such that each graphene film 220 is disposed between one capping layer 230 and the porous membrane 200.

In some embodiments, the step 106 of applying the capping layer 230 to each of the graphene films 220 comprises: applying a layer of yttrium oxide (Y₂O₃) either directly to the graphene film 220 or to an intermediate sublayer. For example, in one embodiment the capping layer comprises a layer of yttrium oxide (Y₂O₃) having a thickness of 1.5 nm.

In the embodiment of the method shown in FIG. 3B, the graphene film 220 acts to close both sides of the porous membrane 200 and to form a smoother and flatter exterior surface of the pellicle. Advantageously, this allows the porous membrane 200 to be protected from etching whilst further reducing EUV flare, regardless of the material used for the capping layer 230.

Furthermore, in addition to being significantly smoother and flatter than a surface of the porous material 200, the surface of the graphene film 220 will have a smaller surface area. Since both capping layers 230 are provided on the graphene film 220 rather than directly on the porous membrane 200, a volume of the capping layer 230 is reduced. Advantageously, this also results in a higher EUV transmissivity of the pellicle for the same thickness of capping layers 230.

The EUV absorption of the two single graphene layer films is about 0.4%. However, since the capping layers 230 are applied to the closed surface of the graphene films 220, rather than the porous CNT membrane 200 there is a reduction in the EUV absorption of the two capping layers. The exact reduction is dependent on the amount of bundling within the CNT membrane 200, however, on average there is a reduction in the EUV absorption of the two capping layers of about 1.5%. Therefore, the addition of a single graphene layer film 220 on each side of the CNTm results in a net gain in EUV transmissivity of around 1.1%.

The combination of the porous CNT membrane 200, the two graphene films 220 and the two capping layers 230 may be referred to as C-G-CNTm-G-C. The EUV transmissivity of the C-G-CNTm-G-C pellicle (for single graphene layer graphene films on both sides, each capped with a 1.5 nm layer of Y₂O₃) is around 94.1%. In contrast, if the same CNTm membrane was capped on both sides with a 1.5 nm layer of Y₂O₃ (without the graphene films 220) the EUV transmissivity of the (C-CNTm-C) pellicle would be around 93% (this value is dependent on the amount of bundling of the CNTs).

The above estimates do not take into account the scattering of EUV radiation by the pellicle, which can lead to loss of EUV radiation of a few %. By closing the structure of the CNT membrane 200 these losses can be avoided or at least reduced. Therefore, in addition to the above-estimated 1.1% gain in EUV transmissivity, the pellicle formed using the method 100 shown in FIG. 2 is expected to further decrease the loss of EUV radiation.

The fact that, in the embodiment of the method shown in FIG. 3B, the graphene films 220 close both sides of the porous membrane 200 has additional advantages, as now discussed.

Within a CNT membrane 200 the carbon nanotubes may be separate or, alternatively, they may clump together in bundles. Furthermore, the size of such bundles may vary. It has been found by the inventors that when a capping layer is applied directly to a CNT membrane, the loss of EUV transmissivity due to a capping layer is strongly dependent on an extent of bundling within the CNT membrane. For example, for a fixed density of CNTs in the membrane, the smaller the number of CNTs per bundle, the larger the loss of EUV transmissivity will be. Advantageously, since both capping layers 230 are applied to the graphene films 220 (rather than the porous membrane 200) the loss of EUV transmissivity is no longer dependent in the typical size of structures within the porous membrane 200 (for example the amount of bundling in the case of a CNT membrane). In fact, by applying the capping layers 230 to the flat graphene films 220, for a given thickness of capping layer 230 the loss of EUV transmissivity is minimized.

The application of the graphene films 220 to one or more sides of a porous membrane 200 may be achieved using a wet transfer process. Such a wet transfer process is known in the art. Typically, the wet transfer process comprises the growth of a two-dimensional material (for example a graphene film 220) on a first substrate (for example a copper substrate). Subsequently, an adhesion layer is formed on the other side of the two-dimensional material. The adhesion layer may, for example, comprise a polymer such as, for example, polymethyl methacrylate (PMMA). Subsequently, the first substrate is removed, for example by selective etching. For example, a first substrate comprising copper may be removed using ammonium persulphate. Optionally, the adhesion layer and the two-dimensional material may be rinsed (for example in water). Subsequently, the two-dimensional material is applied to a side of a porous membrane 200. Finally, the adhesion layer is removed, for example by selective etching.

An alternative method for applying graphene films 220 to one or more side of a porous membrane 200 is now discussed with reference to FIG. 4. FIG. 4 is a schematic representation of a method 300 of applying a graphene film 220 to both sides of a CNT membrane 200. The method 300 may be used for the step 104 in the embodiment of the method for forming a pellicle shown in FIG. 3B.

The method 300 of applying a graphene film 220 to a CNT membrane 200 comprises: providing a graphene film 220 on a support substrate 310; pressing the graphene film 220 to a side of the porous membrane 200; and removing the support substrate 310.

The support substrate 310 comprises a base substrate 312 and a sacrificial layer 314 provided on a surface of the base substrate 312. The graphene film 220 is provided on the sacrificial layer 314.

Although shown schematically as a graphene film 220 being formed and then applied to the sacrificial layer 314 of the support substrate 310 it will be appreciated that, in practice, the graphene film 220 may be formed on the sacrificial layer 314 (i.e. formed in situ).

The graphene film 220 provided on a support substrate 310 may be referred to as a manufacturing intermediate. The method 300 may comprise providing two such manufacturing intermediates.

As shown in the middle right-hand portion of FIG. 4, the method 300 comprises pressing each of the graphene films 220 to a side of the porous membrane 200 by applying pressure through the support substrate 310.

The support substrate 310 may be removed by etching the sacrificial layer 314 to release the base substrate 312 from the graphene film 220.

Some embodiments of the present disclosure relate to a pellicle for use in a lithographic apparatus such as the lithographic apparatus LA shown in FIG. 1. Such a pellicle may, for example, be formed using the method 100 shown schematically in FIG. 2.

Some embodiments of the present disclosure relate to lithographic apparatus operable to form an image of a patterning device on a substrate using a radiation beam. The lithographic apparatus may be generally of the form of the lithographic apparatus LA shown in FIG. 1. The lithographic apparatus LA according to such embodiments further comprises a membrane disposed in a path of the radiation beam B. The membrane may be formed using the method 100 shown schematically in FIG. 2.

In some embodiments, the membrane may form part of a dynamic gas lock. Such a dynamic gas lock may be formed, for example, proximate to an opening for the radiation beam B to pass from a projection system PS of the lithographic apparatus LA to a substrate W supported on a substrate table WT.

In some embodiments, the membrane may form part of a spectral filter. Such a spectral filter may be provided in any convenient or suitable position within the lithographic apparatus. The spectral filter may be arranged to avoid, or at least reduce, out of band radiation from being incident on a substrate supported on a substrate table.

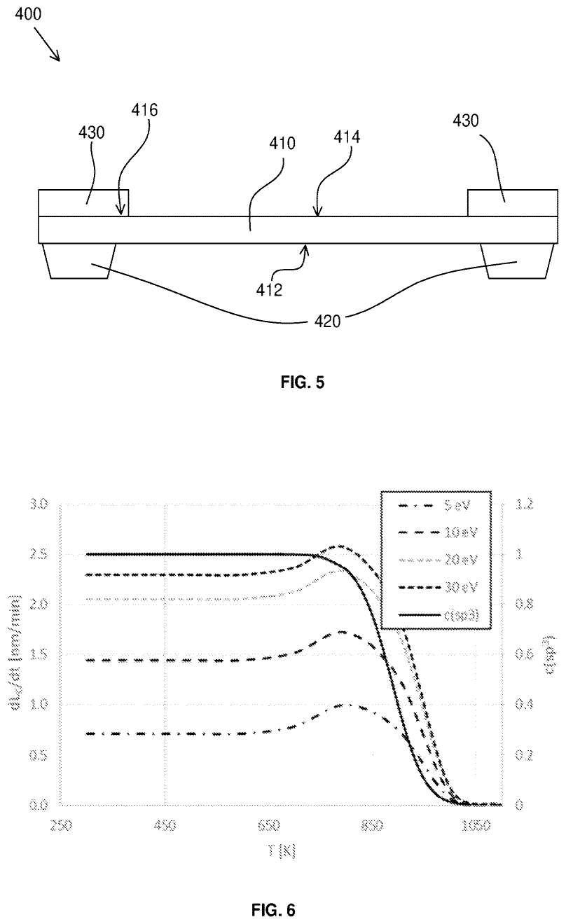

Some embodiments of the present disclosure relate to a pellicle for use in a lithographic apparatus such as the lithographic apparatus LA shown in FIG. 1, as now described with reference to FIG. 5, which shows a schematic cross section of a pellicle 400 according to an embodiment of the present disclosure.

The pellicle 400 comprises: a membrane 410; a border 420; and a protective portion 430. The border 420 is provided at a periphery of, and on a first side 412 of, the membrane 410. The protective portion 430 is provided at a periphery of, and on a second side 414 of, the membrane 410.

The pellicle 400 shown in FIG. 5 is particularly advantageous, as now discussed. As discussed above, the presence of low pressure hydrogen gas within a lithographic apparatus LA can etch pellicles, limiting the potential lifetime of the pellicle. In order to mitigate such etching of pellicles, it has previously been proposed to provide pellicles with a protecting, capping layer. However, it is desirable to minimize the absorption of EUV radiation by the pellicle and therefore the materials and thicknesses of such capping layers are typically rather limited.

The interaction of hydrogen ions with carbon materials is described quantitatively in the following two published papers, the contents of which are hereby incorporated by reference: (1) J. Roth, C. García-Rosales, “Analytic description of the chemical erosion of graphite by hydrogen ions”, Nucl. Fusion 1996, 36/12, 1647-1659; and (2) J. Roth, C. García-Rosales, “Corrigendum —Analytic description of the chemical erosion of graphite by hydrogen ions”, Nucl. Fusion 1997, 37, 897. This quantitative description of the interaction of hydrogen ions with carbon materials may be referred to as Roth-García-Rosales (RGR) model. The RGR model can be used to predict an etch yield of carbon materials as function of the temperature for the typical hydrogen ion energies encountered within the lithographic apparatus such as, for example, ion energies form 1-30 eV. Within an EUV lithographic apparatus a typical hydrogen ion flux incident on the pellicle may be of the order of 1·10¹⁹ m⁻²·s⁻¹. Within an EUV lithographic apparatus a typical hydrogen ion flux incident on the pellicle may be within a couple of orders of magnitude of 1·10¹⁹ m⁻²·s⁻¹ (for example from 10¹⁸ m⁻²·s⁻¹ to 10²⁰ m⁻²·s⁻¹).

FIG. 6 shows an expected etching rate for hydrogen etching of carbon as a function of temperature for a hydrogen ion flux of 1.5·10¹⁹ m⁻²·s⁻¹ for four different ion energies: 5 eV, 10 eV, 20 eV and 30 eV. FIG. 6 also shows an sp3 carbon concentration as a function of temperature. From FIG. 6, it can be seen that for these typical ambient conditions in the lithographic apparatus LA, it is expected that for a pellicle formed purely from CNTs the hydrogen etching rate of the pellicle falls to a negligible level at a temperature of around 1050 K. However, it will be appreciated by the skilled person that under different conditions a different minimum temperature may be desirable.

The inventors of the present invention have realized that the etching of carbon by hydrogen ions and free radicals is temperature dependent. In particular, the inventors have realized that the carbon etching rate is higher at low and intermediate temperatures but the carbon etching rate falls to a negligible level at sufficiently high temperatures. The inventors have also realized that whilst a central portion of a pellicle 19 within an EUV lithographic scanner LA may reach a sufficiently high temperature that hydrogen etching will be negligible (at least part of the time), a periphery of the pellicle will typically remain below this temperature and will therefore be more susceptible to hydrogen etching.

Advantageously, the pellicle 400 shown in FIG. 5 provides an additional protective portion 430 on a portion of (a front side 414 of) the membrane 410 that: (a) is most at risk from hydrogen etching; and (b) in use, does not receive EUV radiation. This allows the lifetime of the pellicle to be increased without affecting the performance of the lithographic apparatus LA.

In some embodiments, the protective portion 430 is provided on a portion of the membrane 410 that, in use, does not receive EUV radiation.

The protective portion 430 may be provided on a portion of the membrane 410 that coincides with the border 420. That is, the protective portion 430 may overlap with the border 420 (but is provided on the opposite side 414 of the pellicle 400). The protective portion 430 may extend partially into a portion 416 of the membrane 410 that does not coincide with the border 420. That is, the protective portion 430 may also extend partially inwards onto a region of the membrane 410 that is not attached to the border 420.

In some embodiments, the protective portion 430 may be formed from the same material as a bulk of the membrane 410. For such embodiments, the protective portion 430 may be an increased thickness of the bulk material (for example a CNT membrane), which may act as a sacrificial portion providing an increased thickness to be etched by the hydrogen.

In some embodiments, the protective portion 430 may be formed from a material that is suitable to protect a portion of the membrane 410 to which it is attached from hydrogen etching. For such embodiments, the protective portion 430 may comprise a capping material. The capping material may comprise any of the following materials either alone or in combination: yttrium (Y), yttrium oxide (YₐO_{b}), aluminium oxide (Al₂O₃), hafnium oxide (HfO₂), zirconium oxide (ZrO₂), ruthenium (Ru), platinum (Pt), gold (Au), zirconium nitride (ZrN), aluminium (Al) or zirconium (Zr). The capping material may comprise a plurality of sublayers formed from different materials.

It will be appreciated that a greater thickness of such a capping material may be provided in the protective portion 430 (relative to a central portion of the membrane 410).

In some embodiments, the membrane 410 comprises nanotubes. For example, the membrane 410 may be a fabric formed from CNTs. This may be referred to as a carbon nanotube membrane. This is a particularly promising material for use as a pellicle membrane in an EUV lithographic apparatus. Such a CNT pellicle is a porous material and, therefore, can provide very high EUV transmission (of >98%). Furthermore, CNT pellicles also provide very good mechanical stability and can therefore be manufactured at small thicknesses, whilst remaining robust against mechanical failure. In other embodiments, the membrane 410 may comprise graphene and/or amorphous carbon.

In some embodiments, the pellicle 400 further comprises a capping material coating at least one surface of the membrane 410.

It will be appreciated that features of the pellicle 400 shown in FIG. 5 and described above may be combined with features of a pellicle formed using the method shown in FIG. 2 and described above.

For example, the membrane 410 may comprise: a porous membrane formed from a first material (for example a CNT membrane); at least one layer of two-dimensional material (for example graphene) adjacent at least one side of the porous membrane; and at least one capping layer adjacent the at least one layer of two-dimensional material such that the at least one layer of two-dimensional material is disposed between the or each capping layer and the porous membrane.

References to a mask or reticle in this document may be interpreted as references to a patterning device (a mask or reticle is an example of a patterning device) and the terms may be used interchangeably. In particular, the term mask assembly is synonymous with reticle assembly and patterning device assembly.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

The term “EUV radiation” may be considered to encompass electromagnetic radiation having a wavelength within the range of 4-20 nm, for example within the range of 13-14 nm. EUV radiation may have a wavelength of less than 10 nm, for example within the range of 4-10 nm such as 6.7 nm or 6.8 nm.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims and clauses set out below.

1. A method for forming a pellicle for use in a lithographic apparatus, the method comprising:
providing a porous membrane formed from a first material;
applying at least one layer of two-dimensional material to at least one side of the porous membrane; and
applying a capping layer to the at least one layer of two-dimensional material on at least one side of the porous membrane such that the at least one layer of two-dimensional material is disposed between the or each capping layer and the porous membrane.
   2. The method of clause 1 wherein the application of at least one layer of two-dimensional material to at least one side of the porous membrane is achieved using a wet transfer process.
   3. The method of clause 1 wherein applying at least one layer of two-dimensional material to at least one side of the porous membrane comprises:
providing at least one layer of two-dimensional material on a support substrate;
pressing the at least one layer of two-dimensional material to a side of the porous membrane; and
removing the support substrate.
   4. The method of clause 3 wherein:
the support substrate comprises a sacrificial layer on a surface thereof;
the at least one layer of two-dimensional material is provided on the sacrificial layer; and removing the support substrate comprises etching the sacrificial layer to remove the support substrate.
   5. The method of any preceding clause wherein the porous membrane comprises a nanostructure.
   6. The method of clause 5 wherein the porous membrane comprises nanotubes.
   7. The method of any preceding clause wherein the porous membrane is substantially self-supporting.
   8. The method of any preceding clause wherein the or each at least one layer of two-dimensional material is applied as a substantially continuous layer adjacent the at least one side of the porous membrane.
   9. The method of any preceding clause wherein the two-dimensional material comprises graphene.
   10. The method of any preceding clause wherein the two-dimensional material comprises hexagonal boron nitride (h-BN).
   11. The method of any preceding clause wherein the two-dimensional material comprises molybdenum disulfide (MoS2).
   12. The method of any preceding clause wherein at least one layer of two-dimensional material is applied to both sides of the porous membrane and wherein a capping layer is applied on each side of the pellicle such that the at least one layer of two-dimensional material is disposed between a capping layer and the porous membrane.
   13. The method of any preceding clause wherein the or each capping layer is a three-dimensional material.
   14. The method of any preceding clause wherein a total EUV transmissivity of the or each capping layer is 96% or more.
   15. The method of any preceding clause wherein the at least one capping layer is suitable to protect the porous layer and the at least one layer of two-dimensional material from hydrogen etching.
   16. The method of any preceding clause wherein the at least one capping layer is formed from a material having an extinction coefficient for EUV radiation of less than 0.02 nm⁻¹.
   17. The method of any preceding clause wherein the capping layer has a thickness of the order of 0.3 to 5 nm.
   18. The method of any preceding clause wherein the capping layer comprises yttrium or yttrium oxide.
   19. The method of any preceding clause wherein the capping layer comprises any of the following: aluminium oxide (Al₂O₃), hafnium oxide (HfO₂), zirconium oxide (ZrO₂), ruthenium (Ru), platinum (Pt), gold (Au), zirconium nitride (ZrN), aluminium (Al) or zirconium (Zr).
   20. The method of any preceding clause further comprising attaching a pellicle border to a periphery of the porous membrane.
   21. The method of clause 20 wherein the pellicle border is attached to the periphery of the porous membrane before the at least one layer of two-dimensional material is applied to at least one side of the porous membrane.
   22. A pellicle for use in a lithographic apparatus, the pellicle comprising:
a porous membrane formed from a first material;
at least one layer of two-dimensional material adjacent at least one side of the porous membrane; and at least one capping layer adjacent the at least one layer of two-dimensional material such that the at least one layer of two-dimensional material is disposed between the or each capping layer and the porous membrane.
   23. The pellicle of clause 22 wherein the porous membrane comprises a nanostructure.
   24. The pellicle of clause 23 wherein the porous membrane comprises nanotubes.
   25. The pellicle of any one of clauses 22 to 24 wherein the porous membrane is substantially self-supporting.
   26. The pellicle of any one of clauses 22 to 25 wherein the or each at least one layer of two-dimensional material forms a substantially continuous layer adjacent the at least one side of the porous membrane.
   27. The pellicle of any one of clauses 22 to 26 wherein the two-dimensional material comprises graphene.
   28. The pellicle of any one of clauses 22 to 27 wherein the two-dimensional material comprises hexagonal boron nitride (h-BN).
   29. The pellicle of any one of clauses 22 to 28 wherein the two-dimensional material comprises molybdenum disulfide (MoS2).
   30. The pellicle of any one of clauses 22 to 29 wherein at least one layer of two-dimensional material is provided adjacent to both sides of the porous membrane and wherein a capping layer is provided on each side of the pellicle such that the at least one layer of two-dimensional material is disposed between a capping layer and the porous membrane.
   31. The pellicle of any one of clauses 22 to 30 wherein the or each capping layer is a three-dimensional material.
   32. The pellicle of any one of clauses 22 to 31 wherein a total EUV transmissivity of the or each capping layer is 96% or more.
   33. The pellicle of any one of clauses 22 to 32 wherein the at least one capping layer is suitable to protect the porous layer and the at least one layer of two-dimensional material from hydrogen etching.
   34. The pellicle of any one of clauses 22 to 33 wherein the at least one capping layer is formed from a material having an extinction coefficient for EUV radiation of less than 0.02 nm⁻¹.
   35. The pellicle of any one of clauses 22 to 34 wherein the capping layer has a thickness of the order of 0.3 to 5 nm.
   36. The pellicle of any one of clauses 22 to 35 wherein the capping layer comprises yttrium or yttrium oxide.
   37. The pellicle of any one of clauses 22 to 36 wherein the capping layer comprises any of the following: aluminium oxide (Al₂O₃), hafnium oxide (HfO₂), zirconium oxide (ZrO₂), ruthenium (Ru), platinum (Pt), gold (Au), zirconium nitride (ZrN), aluminium (Al) or zirconium (Zr).
   38. The pellicle of any preceding clause wherein the capping layer comprises a plurality of sublayers formed from different materials.
   39. The pellicle of any one of clauses 22 to 38 further comprising a pellicle border at a periphery of the porous membrane.
   40. A lithographic apparatus operable to form an image of a patterning device on a substrate using a radiation beam, the lithographic apparatus comprising a membrane disposed in a path of the radiation beam, the membrane comprising:
a porous membrane formed from a first material;
at least one layer of two-dimensional material adjacent at least one side of the porous membrane; and
at least one capping layer adjacent the at least one layer of two-dimensional material such that the at least one layer of two-dimensional material is disposed between the or each capping layer and the porous membrane.
   41. The lithographic apparatus of clause 40 wherein the membrane forms part of a dynamic gas lock.
   42. The lithographic apparatus of clause 40 wherein the membrane forms part of a spectral filter.
   43. The lithographic apparatus of any one of clauses 40 to 42 wherein the porous membrane comprises a nanostructure.
   44. The lithographic apparatus of clause 43 wherein the porous membrane comprises nanotubes.
   45. The lithographic apparatus of any one of clauses 40 to 44 wherein the porous membrane is substantially self-supporting.
   46. The lithographic apparatus of any one of clauses 40 to 45 wherein the or each at least one layer of two-dimensional material forms a substantially continuous layer adjacent the at least one side of the porous membrane.
   47. The lithographic apparatus of any one of clauses 40 to 46 wherein the two-dimensional material comprises graphene.
   48. The lithographic apparatus of any one of clauses 40 to 47 wherein the two-dimensional material comprises hexagonal boron nitride (h-BN).
   49. The lithographic apparatus of any one of clauses 40 to 48 wherein the two-dimensional material comprises molybdenum disulfide (MoS2).
   50. The lithographic apparatus of any one of clauses 40 to 49 wherein at least one layer of two-dimensional material is provided adjacent to both sides of the porous membrane and wherein a capping layer is provided on each side of the membrane such that the at least one layer of two-dimensional material is disposed between a capping layer and the porous membrane.
   51. The lithographic apparatus of any one of clauses 40 to 50 wherein the or each capping layer is a three-dimensional material.
   52. The lithographic apparatus of any one of clauses 40 to 51 wherein the at least one capping layer is suitable to protect the porous layer and the at least one layer of two-dimensional material from hydrogen etching.
   53. The lithographic apparatus of any one of clauses 40 to 52 wherein the at least one capping layer is formed from a material having an extinction coefficient for EUV radiation of less than 0.02 nm⁻¹.
   54. The lithographic apparatus of any one of clauses 50 to 53 wherein the capping layer has a thickness of the order of 0.3 to 5 nm.
   55. The lithographic apparatus of any one of clauses 50 to 54 wherein the capping layer comprises yttrium or yttrium oxide.
   56. The lithographic apparatus of any one of clauses 50 to 55 wherein the capping layer comprises any of the following: aluminium oxide (Al₂O₃), hafnium oxide (HfO₂), zirconium oxide (ZrO₂), ruthenium (Ru), platinum (Pt), gold (Au), zirconium nitride (ZrN), aluminium (Al) or zirconium (Zr).
   57. The lithographic apparatus of any one of clauses 50 to 56 wherein the capping layer comprises a plurality of sublayers formed from different materials.
   58. The lithographic apparatus of any one of clauses 40 to 57 further comprising a membrane border at a periphery of the porous membrane.
   59. A pellicle for use in a lithographic apparatus, the pellicle comprising:
a membrane;
a border at a periphery of, and on a first side of, the membrane; and
a protective portion at a periphery of, and on a second side of, the membrane.
   60. The pellicle of clause 59 wherein the protective portion is provided on a portion of the membrane that, in use, does not receive EUV radiation.
   61. The pellicle of clause 59 or clause 60 wherein the protective portion is provided on a portion of the membrane that coincides with the border.
   62. The pellicle of clause 61 wherein the protective portion extends partially into a portion of the membrane that does not coincide with the border.
   63. The pellicle of any one of clauses 59 to 62 wherein the protective portion is formed from the same material as a bulk of the membrane.
   64. The pellicle of any one of clauses 59 to 63 wherein the protective portion comprises a material that is suitable to protect a portion of the membrane to which it is attached from hydrogen etching.
   65. The pellicle of any one of clauses 59 to 64 wherein the membrane comprises nanotubes, graphene and/or amorphous carbon.
   66. The pellicle of any one of clauses 59 to 65 further comprising a capping material coating at least one surface of the membrane.
   67. The pellicle of any one of clauses 59 to 66, wherein the membrane comprises:
a porous membrane formed from a first material;
at least one layer of two-dimensional material adjacent at least one side of the porous membrane; and at least one capping layer adjacent the at least one layer of two-dimensional material such that the at least one layer of two-dimensional material is disposed between the or each capping layer and the porous membrane.

1. A pellicle for use in a lithographic apparatus, the pellicle comprising:
a porous membrane formed from a first material;
at least one layer of two-dimensional material adjacent at least one side of the porous membrane; and
at least one capping layer adjacent the at least one layer of two-dimensional material such that the at least one layer of two-dimensional material is disposed between the or each capping layer and the porous membrane.

2. The pellicle of claim 1, wherein the porous membrane comprises a nanostructure.

3. The pellicle of claim 1, wherein the porous membrane is substantially self-supporting.

4. The pellicle of claim 1, wherein the or each layer of two-dimensional material forms a substantially continuous layer adjacent the at least one side of the porous membrane.

5. The pellicle of claim 1, wherein the two-dimensional material comprises graphene or nano tubes.

6. The pellicle of claim 1, wherein the two-dimensional material comprises hexagonal boron nitride (h-BN) or molybdenum disulfide (MoS2).

7. The pellicle of claim 1, wherein the at least one layer of two-dimensional material is provided adjacent to both sides of the porous membrane and wherein a capping layer is provided on each side of the pellicle such that the at least one layer of two-dimensional material is disposed between a capping layer and the porous membrane.

8. The pellicle of claim 1, wherein the or each capping layer is a three-dimensional material.

9. The pellicle of claim 1, wherein a total EUV transmissivity of the or each capping layer is 96% or more.

10. The pellicle of claim 1, wherein the at least one capping layer is suitable to protect the porous membrane and the at least one layer of two-dimensional material from hydrogen etching.

11. The pellicle of claim 1, wherein the at least one capping layer is formed from a material having an extinction coefficient for EUV radiation of less than 0.02 nm−¹.

12. The pellicle of claim 1, wherein the at least one capping layer has a thickness of the order of 0.3 to 5 nm.

13. The pellicle of claim 1, wherein the at least one capping layer comprises yttrium or yttrium oxide.

14. The pellicle of claim 1, wherein the at least one capping layer comprises one or more selected from: aluminium oxide (Al₂O₃), hafnium oxide (HfO₂), zirconium oxide (ZrO₂), ruthenium (Ru), platinum (Pt), gold (Au), zirconium nitride (ZrN), aluminium (Al) or zirconium (Zr).

15. The pellicle of claim 1, wherein the at least capping layer comprises a plurality of sublayers formed from different materials.

16. The pellicle of claim 1, further comprising a pellicle border at a periphery of the porous membrane.

17. A method for forming a pellicle for use in a lithographic apparatus, the method comprising:
providing a porous membrane formed from a first material;
applying at least one layer of two-dimensional material to at least one side of the porous membrane; and
applying at least one capping layer to the at least one layer of two-dimensional material on at least one side of the porous membrane such that the at least one layer of two-dimensional material is disposed between the or each capping layer and the porous membrane.

18. A lithographic apparatus operable to form an image of a patterning device on a substrate using a radiation beam, the lithographic apparatus comprising a membrane disposed in a path of the radiation beam, the membrane comprising:
a porous membrane formed from a first material;
at least one layer of two-dimensional material adjacent at least one side of the porous membrane; and
at least one capping layer adjacent the at least one layer of two-dimensional material such that the at least one layer of two-dimensional material is disposed between the or each capping layer and the porous membrane.

19. The lithographic apparatus of claim 18, wherein the membrane forms part of a dynamic gas lock.

20. The lithographic apparatus of claim 18, wherein the membrane forms part of a spectral filter.
